(19) United States
(12) Patent Application Publication
(10) Pub. No.: US 2019/0025369 A1
(43) Pub. Date: Jan. 24, 2019

(54) DISPLAY DEVICE AND METHOD FOR DETECTING ELECTROSTATIC DISCHARGE PHENOMENON THEREOF

(71) Applicant: Chunghwa Picture Tubes, LTD., Taoyuan City (TW)

(72) Inventors: Chang-Xin Huang, Taipei City (TW); Chiao-Lin Huang, New Taipei City (TW)

(73) Assignee: Chunghwa Picture Tubes, LTD., Taoyuan City (TW)

(21) Appl. No.: 15/688,884

(22) Filed: Aug. 29, 2017

(30) Foreign Application Priority Data
Jul. 24, 2017 (CN) 201710605217.9

(51) Int. Cl. G01R 31/28; G09G 3/00; H02H 1/04

(52) U.S. Cl. CPC G01R 31/2856; H02H 1/04; G09G 3/006

(57) ABSTRACT

A display device and a method for detecting an ESD phenomenon are provided. The method including: encoding image data according to an encoding operation to generate a check code; sending the image data and the check code to a receiver by a transmitter, and obtaining a receiving image data and a receiving check code by the receiver; encoding the receiving image data according to the encoding operation to generate a verification check code; and determining whether the ESD phenomenon is occurred by comparing the check code and the verification check code.

### CROSS-REFERENCE TO RELATED APPLICATION

This application claims the priority benefit of China application serial no. 201710605217.9, filed on Jul. 24, 2017. The entirety of the above-mentioned patent application is hereby incorporated by reference herein and made a part of this specification.

### BACKGROUND OF THE INVENTION

### Field of the Invention

The invention relates to a method for detecting an electrostatic discharge (ESD) phenomenon, and particularly relates to a display device and a method for detecting an electrostatic discharge (ESD) phenomenon thereof.

### Description of Related Art

Regarding an ESD phenomenon probably occurred on electronic devices, many methods have been provided to reduce the influence of the ESD phenomenon on the electronic devices. For example, the existing technique provides a circuit network constructed by resistors, capacitors and transient voltage suppressing diodes to drain energy produced by the ESD phenomenon to a ground terminal for excluding the energy out of the system. The existing technique also provides a method of serially connecting inductors, resistors, beads, etc. to an input terminal to block the ESD energy from entering the system.

However, the existing techniques of the field are all passive ESD protection means, which may only reduce the influence of the ESD phenomenon on the electronic devices.

### SUMMARY OF THE INVENTION

The invention is directed to a display device and a method for detecting an electrostatic discharge (ESD) phenomenon thereof, which are adapted to eliminate a damage caused by the ESD phenomenon on a display image.

The invention provides a method for detecting an electrostatic discharge (ESD) phenomenon including: encoding image data according to an encoding operation to generate a check code; sending the image data and the check code to a receiver by a transmitter, and obtaining a receiving image data and a receiving check code by the receiver; encoding the receiving image data according to the encoding operation to generate a verification check code; and determining whether the ESD phenomenon is occurred by comparing the check code and the verification check code.

The invention provides a display device including a display panel, a display data transmitter, a display data receiver and a driving circuit. The display data transmitter encodes image data according to an encoding operation to generate a check code, and sends the image data and the check code. The display data receiver is coupled to the display data transmitter to receive the image data and the check code, and obtains a receiving image data and a receiving check code. The display data receiver encodes the receiving image data according to the encoding operation to generate a verification check code, and determines whether an ESD phenomenon is occurred by comparing the receiving check code and the verification check code. The driving circuit is coupled to the display panel and the display data receiver, and is configured to drive the display panel to perform an image display operation.

According to the above description, the transmitter encodes the image data to produce a check code, and the receiver encodes the received image data to produce a verification check code. By comparing the received check code and the verification check code, the receiver determines whether the received image data is correct data, and determines whether to perform a display operation according to the received image data. In this way, the display image is not spoiled due to the ESD phenomenon, and the influence of the ESD phenomenon on the display device is prevented.

In order to make the aforementioned and other features and advantages of the invention comprehensible, several exemplary embodiments accompanied with figures are described in detail below.

### BRIEF DESCRIPTION OF THE DRAWINGS

The accompanying drawings are included to provide a further understanding of the invention, and are incorporated in and constitute a part of this specification. The drawings illustrate embodiments of the invention and, together with the description, serve to explain the principles of the invention.

FIG. 1 is a flowchart illustrating a method for detecting an electrostatic discharge (ESD) phenomenon according to an embodiment of the invention.

FIG. 2 is a waveform schematic diagram of a sending operation of transfer data.

FIG. 3 is a flowchart illustrating a method for detecting an ESD phenomenon according to another embodiment of the invention.

FIG. 4 is a schematic diagram of a display device according to an embodiment of the invention.

### DESCRIPTION OF EMBODIMENTS

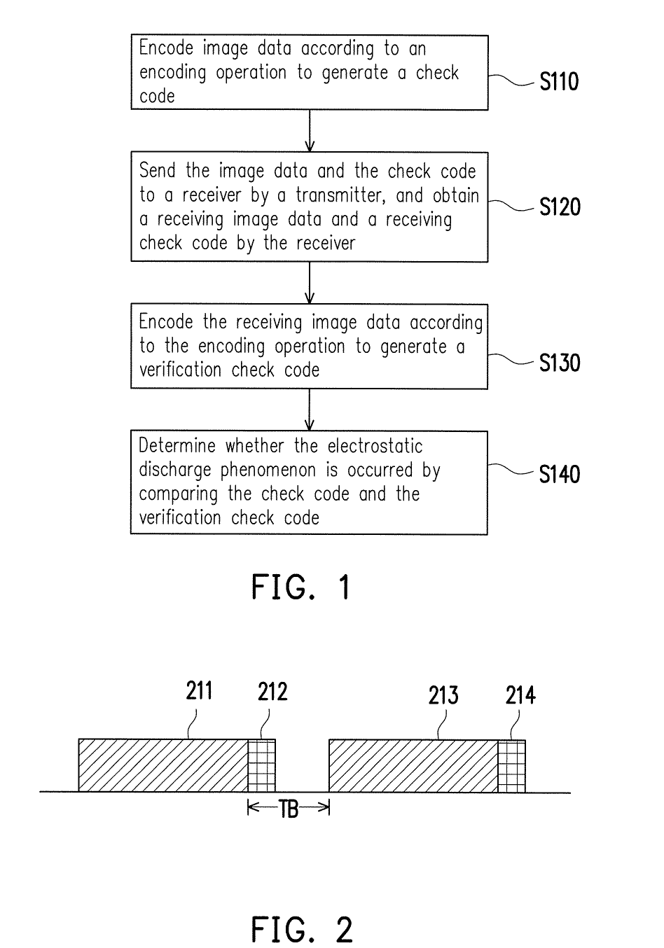

Referring to FIG. 1, FIG. 1 is a flowchart illustrating a method for detecting an electrostatic discharge (ESD) phenomenon according to an embodiment of the invention. The method of the present embodiment may be applied to a display device, and the method for detecting the ESD phenomenon includes following steps. In step S110, image data to be displayed is encoded according to an encoding operation to generate a check code. In the present embodiment, the encoding operation adopted in the step S110 may be implemented by various encoding methods known by related technicians of the field, for example, cyclic redundancy check (CRC) or checksum, etc. In the present embodiment, the above encoding operation may calculate a sum of all data in the image data, and then calculate a complement of the calculated sum to generate the check code. For example, the complement of 1 or the complement of 2 of the calculated sum may be calculated to generate the check code.

For example, when the sum of all data in the image data is equal to 75 of hexadecimal, the corresponding binary data is “0111 0101”, through the calculation of the complement of 1, the check code of the binary data of “1000 1010” is obtained. The mechanism of generating the check code through the calculation of the complement of 1 may simplify design complexity of related hardware.

Then, in step S120, a transmitter sends the image data and the check code to a receiver, and the receiver obtains a receiving image data and a receiving check code. The image data and the corresponding check code may be merged into one transfer data, and the transmitter sends the transfer data to the receiver through a signal transmission interface. The signal transmission interface is not particularly specified, and in the present embodiment, the sending operation of the transfer data may be implemented through a low-voltage differential signal (LVDS) communication protocol. Moreover, the check code may be connected to the corresponding image data to produce the transfer data.

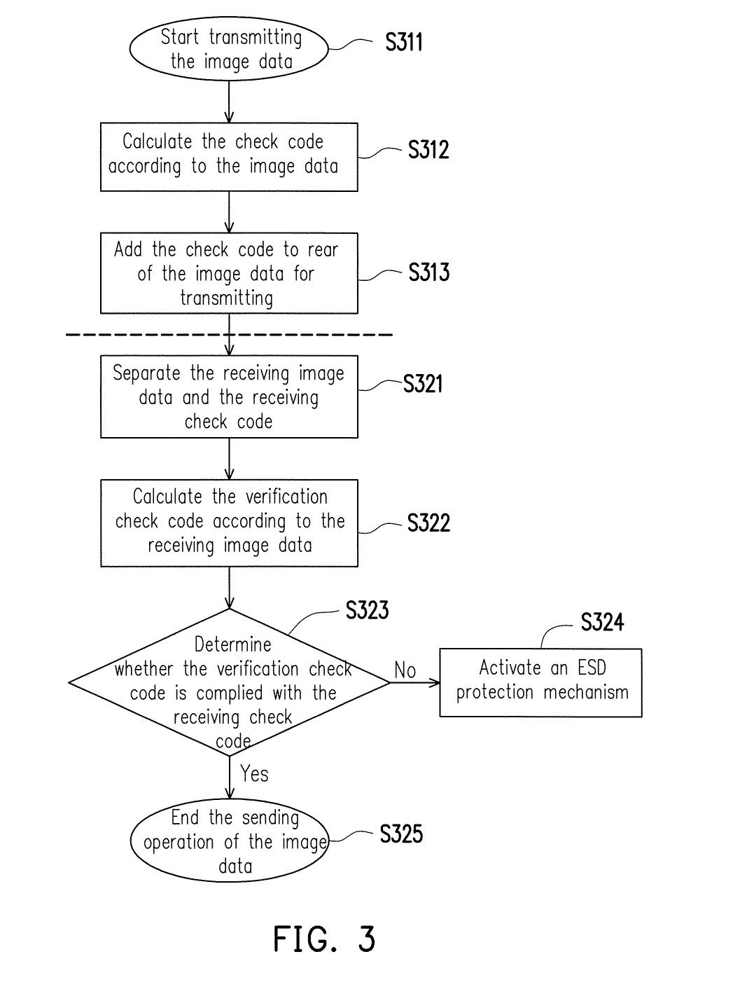

Regarding the sending operation of the transfer data, FIG. 2 is a waveform schematic diagram of a sending operation of transfer data. In FIG. 2, in the sending operation of the image data of the display device, two batches of adjacent image data 211 and 213 have a fixed blank time TB there between. The check codes 212 and 214 respectively corresponding to the image data 211 and the image data 213 are respectively and closely connected to the rear of the corresponding image data 211 and 213 for transfer. By closely connecting the check code 212 corresponding to the image data 211 to the rear of the image data 211 for transfer, the check code 212 may be transferred during the blank time TB without occupying additional time, so as to avoid influencing transmission efficiency of the image data.

Referring to FIG. 1 again, in the step S120, the receiver may receive the transfer data provided by the transmitter through the aforementioned signal transmission interface to obtain a receiving data. It should be noted that the receiving data obtained by the receiver is unnecessarily the same with the transfer data provided by the transmitter, and in some cases (for example, an ESD phenomenon is occurred during the sending process), the transfer data is probably varied due to interference during the sending process, and the receiving data obtained by the receiver is different to the transfer data.

Moreover, in step S120, the receiver may disassemble the receiving data to obtain receiving image data and receiving check code. The disassembling operation of the receiving data is implemented by counting a binary digit capacity of the receiving data and extracting the receiving image data and the receiving check code according to the binary digit capacities of the receiving image data and the receiving check code.

To be specific, if the binary digit capacities of the receiving image data and the receiving check code are respectively N and M, the front N binary digits of the receiving data may be extracted to generate the receiving image data, and the rear M binary digits of the receiving data are extracted to generate the receiving check code. Alternatively, in other embodiments of the invention, a preamble may be added to the front of the check code, and the receiver may identify the preamble in the receiving data for disassembling the receiving image data and the receiving check code. The aforementioned N, M are all positive integers.

Then, in step S130, the receiver performs an encoding operation to the receiving image data to generate a verification check code. The encoding operation of the step S130 and the encoding operation of the step S110 adopt a same encoding method.

In step S140, the verification check code and the receiving check code are compared. As the encoding methods adopted by the step S110 and the step S130 are the same, the verification check code and the receiving check code are the same, which represents that the corresponding receiving image data and the image data are the same. Comparatively, when the verification check code and the receiving check code are not the same, it represents that the corresponding receiving image data and the image data are probably not the same, and it also represents that the ESD phenomenon is probably occurred during the sending process of the image data and the check code, which results in an error of the image data. Therefore, the receiver may determine that the ESD phenomenon is occurred, and activate a corresponding ESD protection mechanism.

It should be noted that the aforementioned image data may be display data of one display row in complete frame data of the display device.

Referring to FIG. 3, FIG. 3 is a flowchart illustrating a method for detecting an ESD phenomenon according to another embodiment of the invention. In view of operations of the transmitter, in step S311, transmission of the image data is started. In step S312, the check code is calculated according to the image data, and in step S313, the check code is added to the rear of the image data, and the check code and the image data are sent altogether.

In view of operations of the receiver, in step S321, the receiving image data and the receiving check code are separated, and in step S322, the verification check code is calculated according to the receiving image data. In step S323, it is determined whether the verification check code equals the receiving check code or not, and if the determination result is affirmative, the sending operation of the image data is ended (step S325). Comparatively if the determination result is negative, the ESD protection mechanism is activated (step S324). In an embodiment of the invention, in case that the ESD protection mechanism is activated, the corresponding image data is abandoned, and is not used by the display device for implementing the image display.

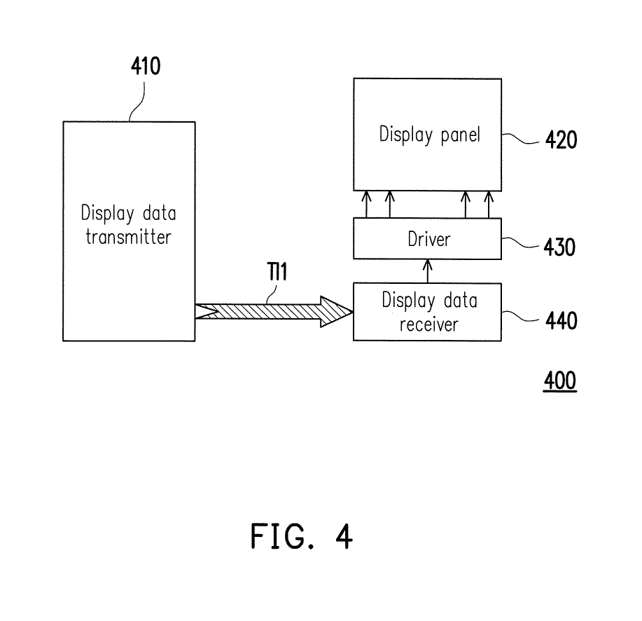

Referring to FIG. 4, FIG. 4 is a schematic diagram of a display device according to an embodiment of the invention. The display device 400 includes a display data transmitter 410, a display panel 420, a driver 430 and a display data receiver 440. The display data transmitter 410 is coupled to the display data receiver 440. The display data transmitter 410 encodes image data according to an encoding operation to generate a check code, and sends the image data and the check code to the display data receiver 440 through a signal transmission interface TI1.

The display data receiver 440 receives the image data and the check code through the signal transmission interface TI1, and obtains a receiving image data and a receiving check code. The display data receiver 440 encodes the receiving image data according to the encoding operation to generate a verification check code, and determines whether the ESD phenomenon is occurred or not by comparing the receiving check code and the verification check code.

The display data receiver 440 is further coupled to the driver 430. When the display data receiver 440 determines that none ESD phenomenon is occurred, the display data receiver 440 transmits the receiving image data to the driver 430, and the driver 430 drives the display panel 420 to display an image according to the receiving image data. Comparatively, when the display data receiver 440 determines that the ESD phenomenon is occurred, the receiving image data is abandoned, so as to prevent displaying an error display image on the display panel 420.

In view of a hardware structure, the display data transmitter 410 and the display data receiver 440 may be processors respectively having a data transmission interface and having a computation capability. Alternatively, the display data transmitter 410 and the display data receiver 440 may also be circuits with a data encoding capability. It should be noted that the display data transmitter 410 and the display data receiver 440 may be designed through a hardware description language (HDL) or design methods of digital circuits well known by those skilled in the art, and implemented through a field programmable gate array (FPGA), a complex programmable logic device (CPLD) or an application-specific integrated circuit (ASIC), which is not limited by the invention.

Moreover, the data transmission interface of the display data transmitter 410 and the display data receiver 440 is a data transmission interface circuit well known by those skilled in the art, which is not limited by the invention.

The driver 430 may be a source driver corresponding to the display panel 420. For example, when the display panel 420 is a liquid crystal display (LCD) panel, the driver 430 is a source driver of a LCD. A hardware structure of the source driver is well known by those skilled in the art, and detail thereof is not repeated.

In summary, the check code is produced at the transmitter, and the verification check code is produced at the receiver according to the receiving image data. By comparing the check code and the verification check code, it is detected whether the ESD phenomenon is occurred or not. Further, when the ESD phenomenon is detected, the ESD protection mechanism is activated to avoid producing an error display image by the display panel, so as to effectively prevent the influence of the ESD phenomenon on the display device.

It will be apparent to those skilled in the art that various modifications and variations can be made to the structure of the invention without departing from the scope or spirit of the invention. In view of the foregoing, it is intended that the invention cover modifications and variations of this invention provided they fall within the scope of the following claims and their equivalents.

What is claimed is:

1. A method for detecting an electrostatic discharge phenomenon, comprising:
encoding image data according to an encoding operation to generate a check code;
sending the image data and the check code to a receiver by a transmitter, and obtaining a receiving image data and a receiving check code by the receiver;
encoding the receiving image data according to the encoding operation to generate a verification check code; and
determining whether the electrostatic discharge phenomenon is occurred by comparing the check code and the verification check code.

2. The method for detecting the electrostatic discharge phenomenon as claimed in claim 1, wherein the step of encoding the image data according to the encoding operation to generate the check code comprises:
calculating a sum of a plurality of data of the image data; and
calculating a complement of the sum of the plurality of data to generate the check code.

3. The method for detecting the electrostatic discharge phenomenon as claimed in claim 2, wherein the step of calculating the complement of the sum of the plurality of data to generate the check code comprises:
calculating the complement of 1 of the sum of the plurality of data to generate the check code.

4. The method for detecting the electrostatic discharge phenomenon as claimed in claim 1, wherein the step of sending the image data and the check code to the receiver by the transmitter comprises:
connecting the check code to the rear of the image data to generate transfer data; and
sending the transfer data to the receiver by the transmitter.

5. The method for detecting the electrostatic discharge phenomenon as claimed in claim 4, wherein the step of obtaining the receiving image data and the receiving check code by the receiver comprises:
receiving the transfer data by the receiver to obtain receiving data; and
disassembling the receiving data to obtain the receiving image data and the receiving check code.

6. The method for detecting the electrostatic discharge phenomenon as claimed in claim 1, wherein the step of determining whether the electrostatic discharge phenomenon is occurred by comparing the check code and the verification check code comprises:
determining that the electrostatic discharge phenomenon is not occurred when the check code equals the verification check code; and
determining that the electrostatic discharge phenomenon is occurred when the check code does not equal the verification check code.

7. The method for detecting the electrostatic discharge phenomenon as claimed in claim 6, wherein when the electrostatic discharge phenomenon is occurred, the method further comprises:
activating an electrostatic discharge protection mechanism to abandon the receiving image data.

8. The method for detecting the electrostatic discharge phenomenon as claimed in claim 1, wherein the image data is display data of a display row in frame data.

9. A display device, comprising:
a display panel;
a display data transmitter, encoding image data according to an encoding operation to generate a check code, and sending the image data and the check code;
a display data receiver, coupled to the display data transmitter, receiving the image data and the check code, and obtaining a receiving image data and a receiving check code, wherein the display data receiver encodes the receiving image data according to the encoding operation to generate a verification check code, and determines whether an electrostatic discharge phenomenon is occurred by comparing the check code and the verification check code; and
a driving circuit, coupled to the display panel and the display data receiver, and driving the display panel to perform an image display operation.

10. The display device as claimed in claim 9, wherein the display data transmitter calculates a sum of a plurality of data of the image data, and calculates a complement of the sum of the plurality of data to generate the check code.

11. The display device as claimed in claim 10, wherein the display data transmitter calculates the complement of 1 of the sum of the plurality of data to generate the check code.

12. The display device as claimed in claim 10, wherein the display data transmitter connects the check code to the rear of the image data to generate transfer data, and sends the transfer data to the display data receiver.

13. The display device as claimed in claim 12, wherein the display data receiver receives the transfer data to obtain receiving data, and disassembles the receiving data to obtain the receiving image data and the receiving check code.

14. The display device as claimed in claim 10, wherein the display data receiver determines that the electrostatic discharge phenomenon is not occurred when the check codes equals the verification check code, and determines that the electrostatic discharge phenomenon is occurred when the check code does not equal the verification check code.

15. The display device as claimed in claim 14, wherein the display data receiver activates an electrostatic discharge protection mechanism to abandon sending the receiving image data to the driving circuit when the electrostatic discharge phenomenon is occurred.

16. The display device as claimed in claim 9, wherein the display data transmitter extracts display data of a display row in frame data to generate the image data.
